(19) United States
(12) Patent Application Publication
(10) Pub. No.: US 2012/0063482 A1
(43) Pub. Date: Mar. 15, 2012

(54) SEMICONDUCTOR LASER ELEMENT, SEMICONDUCTOR LASER DEVICE, AND OPTICAL APPARATUS EMPLOYING THE SAME

(75) Inventors: Shingo Kameyama, Ibaraki-shi (JP); Hiroyuki Yukawa, Kishiwada-shi (JP)

(73) Assignee: Sanyo Electric Co., Ltd., Moriguchi-shi (JP)

(21) Appl. No.: 13/232,265

(22) Filed: Sep. 14, 2011

(30) Foreign Application Priority Data
Sep. 14, 2010 (JP) 2010-205447

(51) Int. Cl. H01S 5/028

(52) U.S. Cl. 372/49.01

(57) ABSTRACT

This semiconductor laser element includes a semiconductor element layer including an active layer and having an emitting side cavity facet and a reflecting side cavity facet, and a facet coating film on a surface of the emitting side cavity facet. The facet coating film includes a first dielectric layer controlling a reflectance of the emitting side cavity facet and a second dielectric layer. A thickness of the second dielectric layer is set to a thickness defined by m×λ/(2×n) (m is an integer), where a wavelength of a laser beam emitted from the active layer is λ. and a refractive index of the second dielectric layer is n, and is larger than a thickness of the first dielectric layer and at least 1 μm.

### CROSS-REFERENCE TO RELATED APPLICATIONS

The priority application number JP2010-205447, Semiconductor Laser Element, Semiconductor Laser Device, and Optical Apparatus Employing the Same, Sep. 14, 2010, Shingo Kameyama et al., upon which this patent application is based, is hereby incorporated by reference.

### BACKGROUND OF THE INVENTION

1. Field of the Invention

The present invention relates to a semiconductor laser element, a semiconductor laser device, and an optical apparatus employing the same, and more particularly, it relates to a semiconductor laser element formed with a facet coating film on a cavity facet, a semiconductor laser device, and an optical apparatus employing the same.

2. Description of the Background Art A semiconductor laser element formed with a facet coating film on a cavity facet is known in general, as disclosed in each of Japanese Patent Laying-Open Nos. 2008-305848 and 2009-21548, for example.

Each of Japanese Patent Laying-Open Nos. 2008-305848 and 2009-21548 discloses a semiconductor laser element made of a nitride-based semiconductor. This semiconductor laser element is formed with a protective film (facet coating film) on a cavity facet on a light-emitting side. This protective film is a dielectric multilayer film in which thin dielectric films each containing Si or Al are stacked. Due to this protective film, the laser reflectance of the cavity facet is set to a prescribed magnitude, and oxidation of the cavity facet is prevented. Thus, the semiconductor laser element disclosed in each of Japanese Patent Laying-Open Nos. 2008-305848 and 2009-21548 can be mounted on an open package type light-emitting device not requiring hermetic sealing of a package.

In Japanese Patent Laying-Open No. 2009-21548, a thin light absorbing film of TiO₂ or the like is further arranged on the outermost surface of the protective film provided on the cavity facet on the light-emitting side. This light absorbing film has a function of partially absorbing an emitted laser beam. Thus, contaminants adhering to the outermost surface of an emitting facet are evaporated again by heat absorbed by the light absorbing film, or adherence of contaminants to the outermost surface itself is inhibited.

However, in the semiconductor laser element disclosed in Japanese Patent Laying-Open No. 2008-305848, the protective film is conceivably provided mainly for the purpose of controlling a laser reflectance. Thus, solid adherent substances (contaminants such as SiOₓ) may be formed on the outermost surface of the protective film by the reaction of water molecules in the atmosphere, low molecular siloxane or volatile organic gas present in minute amounts in the atmosphere, or the like with an emitted laser beam if this semiconductor laser element is mounted on the open package type light-emitting device to operate.

In the semiconductor laser element according to Japanese Patent Laying-Open No. 2009-21548, the light absorbing film is provided on the outermost surface of the protective film, and hence contaminants adhering to the outermost surface (light absorbing film) of the protective film are conceivably removed to some extent by heat accumulated in the light absorbing film. However, in a blue-violet semiconductor laser element having a short lasing wavelength of about 405 nm or the like, adherence of contaminants to an emitting facet tends to be significantly promoted due to an increase in light energy (light density). Therefore, in the semiconductor laser element according to Japanese Patent Laying-Open No. 2009-21548 including the thin protective film and light absorbing film, the amount of deposition of contaminants may exceed the amount of removal of contaminants, and adherence of contaminants to the outermost surface of an emitting facet cannot be reliably inhibited.

### SUMMARY OF THE INVENTION

A semiconductor laser element according to a first aspect of the present invention includes a semiconductor element layer including an active layer and having an emitting side cavity facet and a reflecting side cavity facet, and a facet coating film on a surface of the emitting side cavity facet, wherein the facet coating film includes a first dielectric layer controlling a reflectance of the emitting side cavity facet and a second dielectric layer, and a thickness of the second dielectric layer is set to a thickness defined by m×λ/(2×n) (m is an integer), where a wavelength of a laser beam emitted from the active layer is λ and a refractive index of the second dielectric layer is n, and is larger than a thickness of the first dielectric layer and at least 1 μm.

In the present invention, the emitting side cavity facet and the reflecting side cavity facet are distinguished from each other through the large-small relation between the intensity levels of laser beams emitted from a pair of cavity facets formed. In other words, the emitting side cavity facet has relatively larger light intensity of the laser beam, and the reflecting side cavity facet has relatively smaller light intensity of the laser beam.

In the semiconductor laser element according to the first aspect of the present invention, as hereinabove described, the facet coating film includes the first dielectric layer controlling the reflectance and the second dielectric layer, and the thickness of the second dielectric layer is set to a thickness defined by m×λ/(2×n) and is larger than the thickness of the first dielectric layer and at least 1 μm. Thus, the thickness of the second dielectric layer is larger than the thickness of the first dielectric layer and has no influence on the reflectance, and hence the first dielectric layer can easily control the reflectance of the emitting side cavity facet without any influence of the second dielectric layer. Further, the thick second dielectric layer can effectively reduce the light density on an outermost surface. Thus, formation of contaminants on the outermost surface of the emitting side cavity facet resulting from the reaction of water molecules in the atmosphere, low molecular siloxane or volatile organic gas present in minute amounts in the atmosphere, or the like with an emitted laser beam can be reliably inhibited. Consequently, the semiconductor laser element can stably operate.

Further, in the semiconductor laser element according to the first aspect, as hereinabove described, contaminants hardly adhere to the outermost surface of the emitting side cavity facet, and hence no closed type package hermetically sealing the semiconductor laser element is required.

In the aforementioned semiconductor laser element according to the first aspect, the second dielectric layer is preferably made of a SiO₂ film. According to this structure, an oxide film of SiO₂ having a small film stress is employed even if the thickness of the second dielectric layer is large, at least 1 μm, and hence the film stress of the thick second dielectric layer can be reduced as much as possible. The thickness of the second dielectric layer is preferably not more than 2.5 μm. According to this structure, separation of the second dielectric layer from the emitting side cavity facet can be rendered hard to generate, and the control of the thickness can be maintained.

In the aforementioned semiconductor laser element according to the first aspect, the second dielectric layer preferably has a multi-layer film structure made of a plurality of dielectric layers, and a thickness of each of the plurality of dielectric layers is preferably set to a thickness defined by m×λ/(2×n) (m is an integer), where the wavelength of the laser beam emitted from the active layer is λ and a refractive index of each of the plurality of dielectric layers is n, while the thickness of the second dielectric layer is preferably larger than the thickness of the first dielectric layer and at least 1 μm. According to this structure, the thickness of the second dielectric layer is larger than the thickness of the first dielectric layer and has no influence on the reflectance even if the second dielectric layer has a multi-layer film structure, and hence the first dielectric layer can easily control the reflectance of the emitting side cavity facet without any influence of the second dielectric layer. Further, the thick second dielectric layer can effectively reduce the light density on the outermost surface. Thus, formation of contaminants on the outermost surface of the emitting side cavity facet can be reliably inhibited, and hence the semiconductor laser element can stably operate.

In the aforementioned structure in which the second dielectric layer has the multi-layer film structure made of the plurality of dielectric layers, the second dielectric layer preferably has the multi-layer film structure obtained by stacking a first layer of SiO₂ and a second layer of AlON, and a thickness of the first layer is preferably larger than a thickness of the second layer. According to this structure, the thickness of the second layer of an oxynitride film (AlON) with a relatively larger film stress is rendered smaller than the thickness of the first layer of an oxide film (SiO₂) with a relatively smaller film stress to form the second dielectric layer, and hence an excessive increase in the film stress of the thick second dielectric layer can be inhibited.

In this case, at least two first layers and at least two second layers are preferably alternately stacked in the second dielectric layer. According to this structure, the second dielectric layer can be formed by repeatedly alternately arranging an oxynitride film with a relatively larger film stress and an oxide film with a relatively smaller film stress, and hence the thick second dielectric layer can be easily formed while an excessive increase in the film stress is inhibited.

In the aforementioned semiconductor laser element according to the first aspect, the first dielectric layer is preferably a single-layer dielectric film having a thickness other than a thickness defined by m×λ/(2×n) (m is an integer) or a dielectric film made of a plurality of layers each having a thickness other than a thickness defined by m×λ/(2×n) (m is an integer). According to this structure, the first dielectric layer can be simply formed because of a single layer if the first dielectric layer is the single-layer dielectric film. If the first dielectric layer is the dielectric film made of the plurality of layers, the first dielectric layer for obtaining a desired reflectance can be formed by finely controlling the thickness of each of the plurality of layers.

In this case, at least one layer of the dielectric film preferably has a thickness of λ/(4×n) or approximately λ/(4×n) if the first dielectric layer is the dielectric film made of the plurality of layers. According to this structure, the first dielectric layer for obtaining a desired reflectance can be easily formed even if the first dielectric layer is constituted by a dielectric film formed of two layers.

In the aforementioned semiconductor laser element according to the first aspect, the refractive index of the second dielectric layer is preferably smaller than a refractive index of the first dielectric layer. According to this structure, the thickness of the second dielectric layer can be easily rendered larger than the thickness of the first dielectric layer.

In the aforementioned semiconductor laser element according to the first aspect, the first dielectric layer and the second dielectric layer are preferably in contact with each other. According to this structure, another dielectric layer does not lie between the first dielectric layer and the second dielectric layer, and hence the first dielectric layer can efficiently control the reflectance for an emitted laser beam while the second dielectric layer can efficiently control the reduction in the light density of the emitted laser beam. Consequently, a laser beam, the reflectance for which and the light density of which are controlled to be desired ones, can be easily emitted from the outermost surface of the facet coating film.

In the aforementioned semiconductor laser element according to the first aspect, the first dielectric layer and the second dielectric layer are preferably formed in this order from a side closer to the emitting side cavity facet in the facet coating film. According to this structure, the first dielectric layer determining the reflectance can be brought close to the emitting side cavity facet of the semiconductor element layer hardly influenced by surface roughness, and hence the first dielectric layer, the thicknesses of which are more accurately controlled in a film forming process, can be formed. Thus, a desired reflectance can be accurately obtained.

In this case, the second dielectric layer is preferably arranged on an outermost surface of the facet coating film. According to this structure, the light density of an emitted laser beam is effectively reduced on the outermost surface of the facet coating film on which the second dielectric layer is arranged, and hence formation of contaminants on the surface of the second dielectric layer can be reliably inhibited. Thus, the semiconductor laser element in which the second dielectric layer of the facet coating film is inhibited from degradation can be obtained.

In the aforementioned semiconductor laser element according to the first aspect, the facet coating film preferably further includes a third dielectric layer made of a photocatalyst material on an outermost surface opposite to the emitting side cavity facet. According to this structure, formation of contaminants on the outermost surface of the emitting side cavity facet can be further inhibited due to photocatalytic action of the third dielectric layer.

In the aforementioned structure in which the facet coating film further includes the third dielectric layer, the third dielectric layer preferably includes a microcrystalline layer of TiO₂ and an amorphous layer of TiO₂. According to this structure, the third dielectric layer reliably having photocatalytic action can be formed.

In the aforementioned structure in which the facet coating film further includes the third dielectric layer, a thickness of the third dielectric layer is preferably set to a thickness defined by m×λ/(2×n) (m is an integer) and is preferably smaller than the thickness of the second dielectric layer. According to this structure, the absorption of a laser beam, the light density of which is properly reduced by the second dielectric layer, into the third dielectric layer can be inhibited as much as possible. Thus, abnormal heat generation on the outermost surface (third dielectric layer) of the facet coating film can be inhibited, and hence formation of contaminants on the outermost surface of the facet coating film can be more reliably inhibited.

In the aforementioned structure in which the facet coating film further includes the third dielectric layer, a refractive index of the third dielectric layer is preferably larger than the refractive index of the second dielectric layer. According to this structure, the thickness of the third dielectric layer can be easily rendered smaller (thinner) than the thickness of the second dielectric layer.

In the aforementioned structure in which the facet coating film further includes the third dielectric layer, the first dielectric layer, the second dielectric layer, and the third dielectric layer are preferably formed in this order from a side closer to the emitting side cavity facet in the facet coating film. According to this structure, in the facet coating film, an emitted laser beam is transmitted through the first dielectric layer to accurately obtain a desired reflectance, and thereafter transmitted through the second dielectric layer to properly reduce the light density, and thereafter transmitted through the third dielectric layer arranged on the outermost surface, and hence formation of contaminants on the outermost surface of the emitting side cavity facet can be effectively inhibited due to photocatalytic action of the third dielectric layer.

In this case, the third dielectric layer is preferably formed on the second dielectric layer through a nitride film. According to this structure, the third dielectric layer can be improved in crystallinity by the nitride film lying between the second dielectric layer and the third dielectric layer. Thus, the photocatalytic effect of the third dielectric layer can be enhanced.

In the aforementioned semiconductor laser element according to the first aspect, the semiconductor element layer is preferably made of a nitride-based semiconductor. When the semiconductor laser element is made of a nitride-based semiconductor, a laser beam with a shorter wavelength (400 nm band) is emitted from the semiconductor laser element, as compared with a red or infrared semiconductor laser element made of a GaAs-based semiconductor or the like. Further, the nitride-based semiconductor laser element requires a higher output power in response to a double speed optical disk system or an increased storage capacity. In the semiconductor laser element emitting a laser beam with a shorter wavelength and requiring a higher output power, adherence of contaminants to the outermost surface of an emitting facet tends to be significantly promoted due to an increase in the light density on the emitting side cavity facet. Therefore, the nitride-based semiconductor laser element includes the “facet coating film” in the present invention, whereby adherence of contaminants to the outermost surface of an emitting facet can be effectively reliably inhibited.

A semiconductor laser device according to a second aspect of the present invention includes a semiconductor laser element including a semiconductor element layer including an active layer and having an emitting side cavity facet and a reflecting side cavity facet, and a facet coating film on a surface of the emitting side cavity facet, and an open-to-atmosphere-type package mounting with the semiconductor laser element, wherein the facet coating film has a first dielectric layer controlling a reflectance of the emitting side cavity facet and a second dielectric layer, and a thickness of the second dielectric layer is set to a thickness defined by m×λ/(2×n) (m is an integer), where a wavelength of a laser beam emitted from the active layer is λ and a refractive index of the second dielectric layer is n, and is larger than a thickness of the first dielectric layer and at least 1 μm.

The semiconductor laser device according to the second aspect of the present invention includes the semiconductor laser element having the aforementioned structure, and hence formation of contaminants on an outermost surface of the emitting side cavity facet of the semiconductor laser element can be reliably inhibited. Consequently, the reliable semiconductor laser device capable of stably operating the semiconductor laser element and enduring the use for a long time can be obtained.

Further, the semiconductor laser device according to the second aspect includes the open-to-atmosphere-type package as hereinabove described, and hence the structure of the semiconductor laser device can be simplified.

An optical apparatus according to a third aspect of the present invention includes a semiconductor laser device including a semiconductor laser element having a semiconductor element layer including an active layer and having an emitting side cavity facet and a reflecting side cavity facet, and a facet coating film on a surface of the emitting side cavity facet, and an open-to-atmosphere-type package mounting with the semiconductor laser element, and an optical system controlling a beam emitted from the semiconductor laser element, wherein the facet coating film has a first dielectric layer controlling a reflectance of the emitting side cavity facet and a second dielectric layer, and a thickness of the second dielectric layer is set to a thickness defined by m×λ/(2×n) (m is an integer), where a wavelength of a laser beam emitted from the active layer is λ and a refractive index of the second dielectric layer is n, and is larger than a thickness of the first dielectric layer and at least 1 μm.

The optical apparatus according to the third aspect of the present invention includes the semiconductor laser device including the semiconductor laser element having the aforementioned structure, and hence formation of contaminants on an outermost surface of the emitting side cavity facet of the semiconductor laser element can be reliably inhibited. Consequently, the optical apparatus mounted with the reliable semiconductor laser device capable of enduring the use for a long time can be easily obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view of a blue-violet semiconductor laser element according to a first embodiment of the present invention in a state cut parallelly to a cavity direction;

FIG. 2 is a longitudinal sectional view of the blue-violet semiconductor laser element according to the first embodiment of the present invention in a state cut perpendicularly to the cavity direction;

FIG. 3 is a diagram showing results of a confirmatory experiment conducted to confirm the effects of the first embodiment of the present invention;

FIG. 4 is a longitudinal sectional view of a blue-violet semiconductor laser element according to a modification of the first embodiment of the present invention in a state cut parallelly to a cavity direction;

FIG. 5 is a longitudinal sectional view of a blue-violet semiconductor laser element according to a second embodiment of the present invention in a state cut parallelly to a cavity direction;

FIG. 6 is a longitudinal sectional view of a blue-violet semiconductor laser element according to a third embodiment of the present invention in a state cut parallelly to a cavity direction;

FIG. 7 is a diagram showing results of a confirmatory experiment conducted to confirm the effects of the third embodiment of the present invention;

FIG. 8 is a longitudinal sectional view of a blue-violet semiconductor laser element according to a fourth embodiment of the present invention in a state cut parallelly to a cavity direction;

FIG. 9 is a longitudinal sectional view of a blue-violet semiconductor laser element according to a fifth embodiment of the present invention in a state cut parallelly to a cavity direction;

FIG. 10 is a longitudinal sectional view of a blue-violet semiconductor laser element according to a sixth embodiment of the present invention in a state cut parallelly to a cavity direction;

FIG. 11 is a longitudinal sectional view of a blue-violet semiconductor laser element according to a seventh embodiment of the present invention in a state cut parallelly to a cavity direction;

FIG. 12 is a perspective view showing the structure of a semiconductor laser device mounted with a three-wavelength semiconductor laser element according to an eighth embodiment of the present invention; and

FIG. 13 is a schematic diagram showing the structure of an optical pickup mounted with a semiconductor laser device according to a ninth embodiment of the present invention.

### DESCRIPTION OF THE PREFERRED EMBODIMENTS

Embodiments of the present invention are hereinafter described with reference to the drawings.

### First Embodiment

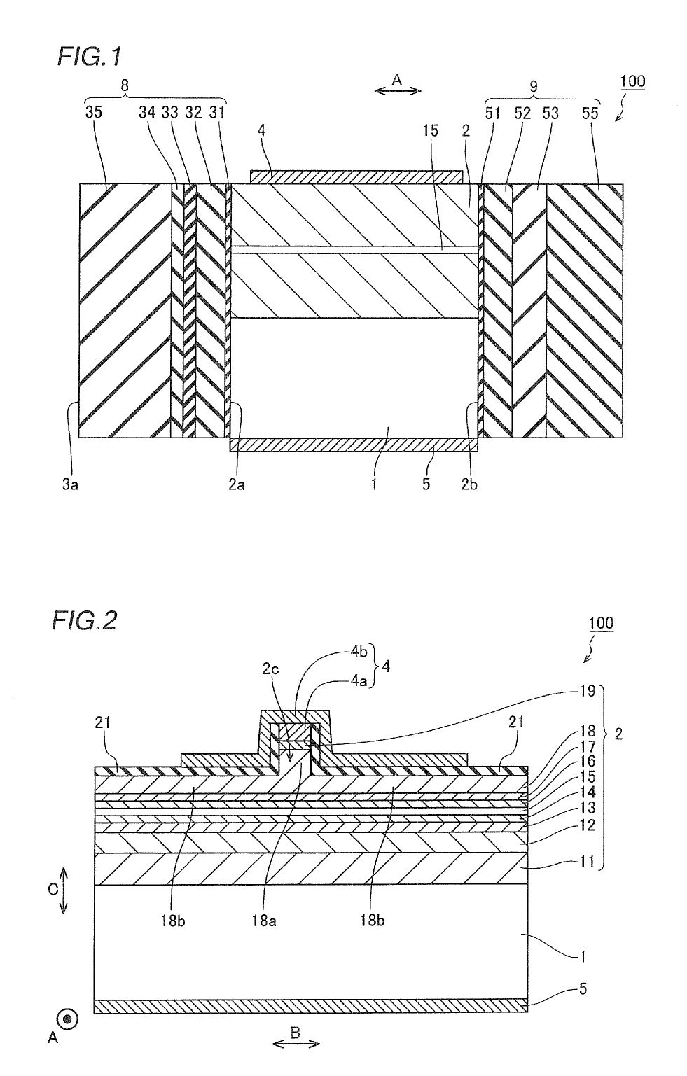

The structure of a blue-violet semiconductor laser element 100 according to a first embodiment of the present invention is now described with reference to FIGS. 1 and 2. The blue-violet semiconductor laser element 100 is an example of the “semiconductor laser element” in the present invention.

The blue-violet semiconductor laser element 100 has a lasing wavelength of about 405 nm and is formed with a semiconductor element layer 2 made of a plurality of nitride-based semiconductor layers including an active layer 15 on a surface of an n-type GaN substrate 1, as shown in FIG. 1. A p-side electrode 4 is formed on the upper surface of the semiconductor element layer 2, and an n-side electrode 5 is formed on the lower surface of the n-type GaN substrate 1. The semiconductor element layer 2 is formed with cavity facets 2a and 2b orthogonal to the extensional direction (direction A) of a cavity, and facet coating films 8 and 9 are formed on the cavity facets 2a and 2b, respectively. The cavity facets 2a and 2b are examples of the “emitting side cavity facet” and the “reflecting side cavity facet” in the present invention, respectively.

The facet coating film 8 has a multi-layer film structure obtained by stacking a plurality of inorganic dielectric layers on the cavity facet 2a in prescribed order. Specifically, the facet coating film 8 is constituted by an AlN film 31 having a thickness of about 10 nm coming into contact with the cavity facet 2a, an Al₂O₃ film 32 having a thickness of about 120 nm, a SiO₂ film 33 having a thickness of about 68 nm, an Al₂O₃ film 34 having a thickness of about 60 nm, and a single-layer SiO₂ film 35 having a thickness of about 1095 nm. The surface of the SiO₂ film 35 is an outermost surface 3a of an emitting facet. Two layers of the AlN film 31 and the Al₂O₃ film 32 have a function of preventing oxidation of the cavity facet 2a. Two layers of the SiO₂ film 33 and the Al₂O₃ film 34 have a function of controlling the laser reflectance of the cavity facet 2a. The SiO₂ film 33 and the Al₂O₃ film 34 are an example of the “first dielectric layer” in the present invention, and the SiO₂ film 35 is an example of the “second dielectric layer” in the present invention.

According to the first embodiment, the thickness (about 68 nm) of the SiO₂ film 33 is set by applying a relational expression shown by m×λ/(4×n) (m=1), where the refractive index of SiO₂ is n (=about 1.48).

The thickness (about 60 nm) of the Al₂O₃ film 34 is set by applying the relational expression shown by m×λ/(4×n) (m=1), where the refractive index of Al₂O₃ is n (=about 1.68). Thus, each of the SiO₂ film 33 and the Al₂O₃ film 34 is set to a thickness other than m×λ/(2×n). Thus, the laser reflectance of the cavity facet 2a is set to about 25%.

According to the first embodiment, the thickness (about 1095 nm) of the SiO₂ film 35 is set by applying a relational expression shown by m×λ/(2×n) (m=8), where the refractive index of SiO₂ is n (=about 1.48). Thus, a laser beam is transmitted to the outermost surface 3a without being reflected in the SiO₂ film 35. The thickness of the SiO₂ film 35 is much larger than the total thickness of the SiO₂ film 33 and the Al₂O₃ film 34 controlling the reflectance, and hence the light density of the laser beam transmitted through the SiO₂ film 35 is gradually reduced as the laser beam approaches the outermost surface 3a. The refractive index of the SiO₂ film 35 is preferably smaller than the refractive index of either of the two dielectric layers constituting the “first dielectric layer” in the present invention. In this case, the refractive index of the SiO₂ film 35 is smaller than the refractive index of the Al₂O₃ film 34. Further, the refractive index of the “second dielectric layer” in the present invention is preferably smaller than the refractive index of any one of dielectric layers constituting the “first dielectric layer” when the “first dielectric layer” in the present invention has the aforementioned two-layer structure or a multi-layer film structure of three or more layers. Alternatively, the refractive index of the “second dielectric layer” is more preferably smaller than the refractive index of each of the dielectric layers constituting the “first dielectric layer”.

The facet coating film 9 also has a multi-layer film structure obtained by stacking a plurality of inorganic dielectric layers on the cavity facet 2b in prescribed order. Specifically, the facet coating film 9 is constituted by an AlN film 51 having a thickness of about 10 nm coming into contact with the cavity facet 2b, an Al₂O₃ film 52 having a thickness of about 120 nm, a SiO₂ film 53 having a thickness of about 140 nm, and a multilayer reflecting film 55 having a thickness of about 340 nm. The multilayer reflecting film 55 has a structure obtained by alternately stacking three SiO₂ films each having a thickness of about 68 nm as a low refractive index film and three ZrO₂ films each having a thickness of about 45 nm as a high refractive index film, and the laser reflectance of the cavity facet 2b is set to about 80% due to the multilayer reflecting film 55.

In the semiconductor element layer 2, an n-type layer 11 is formed on the n-type GaN substrate 1, as shown in FIG. 2. An n-type cladding layer 12 is formed on the n-type layer 11. An n-type carrier blocking layer 13 is formed on the n-type cladding layer 12. An n-side optical guiding layer 14 is formed on the n-type carrier blocking layer 13. The active layer 15 having a multiple quantum well (MQW) structure obtained by alternately stacking four barrier layers (not shown) of GaN and three quantum well layers (not shown) of InGaN having a higher In composition is formed on the n-side optical guiding layer 14.

A p-side optical guiding layer 16 is formed on the active layer 15. A p-type cap layer 17 is formed on the p-side optical guiding layer 16. A p-type cladding layer 18 is formed on the p-type cap layer 17. The p-type cladding layer 18 is constituted by a projecting portion 18a, having a width of about 1.5 μm, extending in the [1-100] direction (direction A) in a striped manner and planar portions 18b extending on both sides of the projecting portion 18a.

A p-side contact layer 19 is formed on the projecting portion 18a of the p-type cladding layer 18. This p-side contact layer 19 and the projecting portion 18a of the p-type cladding layer 18 form a ridge portion 2c extending in the direction A in a striped manner. The ridge portion 2c constitutes a current injection portion, while a waveguide extending in the [1-100] direction (direction A) in a striped manner along the ridge portion 2c is formed in a region, including the active layer 15, located under the ridge portion 2c. The n-type layer 11, the n-type cladding layer 12, the n-type carrier blocking layer 13, the n-side optical guiding layer 14, the active layer 15, the p-side optical guiding layer 16, the p-type cap layer 17, the p-type cladding layer 18, and the p-side contact layer 19 are examples of the “semiconductor element layer” in the present invention.

A current blocking layer 21 of SiO₂ having a thickness of about 0.3 μm is formed on the side surfaces of the projecting portion 18a of the p-type cladding layer 18 and the upper surfaces of the planar portions 18b thereof. The current blocking layer 21 is formed to expose the upper surface of the ridge portion 2c (upper surface of the p-side contact layer 19) other than regions near the cavity facets 2a and 2b.

The p-side electrode 4 is constituted by an ohmic electrode 4a formed to be in contact with the upper surface of the ridge portion 2c and a p-side pad electrode 4b formed on the ohmic electrode 4a and the current blocking layer 21. In the ohmic electrode 4a, a Pt layer having a thickness of about 5 nm, a Pd layer having a thickness of about 100 nm, and an Au layer having a thickness of about 150 nm are stacked in this order from the side closer to the p-side contact layer 19. In the p-side pad electrode 4b, a Ti layer having a thickness of about 0.1 μm, a Pd layer having a thickness of about 0.1 μm, and an Au layer having a thickness of about 3 μm are stacked in this order from the side closer to the ohmic electrode 4a and the current blocking layer 21.

In the n-side electrode 5, an Al layer having a thickness of about 10 nm, a Pt layer having a thickness of about 20 nm, and an Au layer having a thickness of about 300 nm are stacked in this order from the side closer to the n-type GaN substrate 1.

A manufacturing process for the blue-violet semiconductor laser element 100 is now described with reference to FIGS. 1 and 2.

First, the n-type layer 11, the n-type cladding layer 12, the n-type carrier blocking layer 13, the n-side optical guiding layer 14, and the active layer 15 are successively formed on the n-type GaN substrate 1 by metal organic vapor phase epitaxy (MOVPE), as shown in FIG. 2. Further, the p-side optical guiding layer 16, the p-type cap layer 17, the p-type cladding layer 18, and the p-side contact layer 19 are successively formed on the active layer 15. Thereafter, p-type annealing treatment and formation of the ridge portion 2c by etching are performed.

Thereafter, the ohmic electrode 4a is formed on the ridge portion 2c, while the current blocking layer 21 is formed by vacuum evaporation. The upper surface of the ohmic electrode 4a is exposed by removing the current blocking layer 21 on the ohmic electrode 4a, and thereafter the p-side pad electrode 4b is formed on the current blocking layer 21 to be in contact with the upper surface of the ohmic electrode 4a. Further, the n-side electrode 5 is formed on the lower surface of the n-type GaN substrate 1 by vacuum evaporation. Thus, a wafer of the blue-violet semiconductor laser element 100 is prepared.

Next, scribed lines are formed on the upper surface of the wafer of the blue-violet semiconductor laser element 100 in a direction orthogonal to the extensional direction of the ridge portion 2c. These scribed lines are formed on a portion excluding the ridge portion 2c in the form of broken lines.

Then, the wafer of the blue-violet semiconductor laser element 100 is cleaved along the scribed lines, to form a wafer in a bar state. Thereafter, the wafer in a bar state is introduced into an electron cyclotron resonance (ECR) sputtering film deposition apparatus.

ECR plasma is applied to the cavity facet 2a (see FIG. 1) formed by the aforementioned cleavage for 5 minutes, thereby cleaning the cavity facet 2a. The ECR plasma is generated under a condition of a microwave output of 500 W in a N2 gas atmosphere of about 0.02 Pa. At this time, the cavity facet 2a is slightly etched. In this case, no RF power is applied to a sputtering target.

Then, the AlN film 31 is formed on the cavity facet 2a under conditions of an Ar gas flow rate of about 20 sccm, a N₂ gas flow rate of about 4.5 sccm, a microwave output of 500 W, and RF power of 500 W by ECR sputtering, employing Al as a metal target. Thereafter, the Al₂O₃ film 32 is formed on the AlN film 31 under conditions of an Ar gas flow rate of about 20 sccm, an O₂ gas flow rate of about 5 sccm, a microwave output of 500 W, and RF power of 500 W, employing Al as a metal target. Thereafter, the SiO₂ film 33 is formed on the Al₂O₃ film 32 under conditions of an Ar gas flow rate of about 20 sccm, an O₂ gas flow rate of about 7 sccm, a microwave output of 500 W, and RF power of 500 W, employing Si as a metal target. Thereafter, the Al₂O₃ film 34 is formed on the SiO₂ film 33 under conditions of an Ar gas flow rate of about 20 sccm, an O₂ gas flow rate of about 5 sccm, a microwave output of 500 W, and RF power of 500 W, employing Al as a metal target. Thereafter, the SiO₂ film 35 is formed on the Al₂O₃ film 34 under conditions of an Ar gas flow rate of about 20 sccm, an O₂ gas flow rate of about 7 sccm, a microwave output of 500 W, and RF power of 500 W, employing Si as a metal target. Thus, the facet coating film 8 is formed on the cavity facet 2a.

Thereafter, similarly to the aforementioned cavity facet 2a, ECR plasma is applied to the other cavity facet 2b (see FIG. 1) formed by the aforementioned cleavage, thereby cleaning the cavity facet 2b.

Thereafter, the AlN film 51 is formed on the cavity facet 2b under conditions of an Ar gas flow rate of about 20 sccm, a N₂ gas flow rate of about 4.5 sccm, a microwave output of 500 W, and RF power of 500 W, employing Al as a metal target. Thereafter, the Al₂O₃ film 52 is formed on the AlN film 51 under conditions of an Ar gas flow rate of about 20 sccm, an O₂ gas flow rate of about 4 sccm, a microwave output of 500 W, and RF power of 500 W, employing Al as a metal target. Thereafter, the SiO₂ film 53 is formed on the Al₂O₃ film 52 under conditions of an Ar gas flow rate of about 20 sccm, an O₂ gas flow rate of about 7 sccm, a microwave output of 500 W, and RF power of 500 W, employing Si as a metal target. Thereafter, the SiO₂ film is formed on the SiO₂ film 53 under conditions of an Ar gas flow rate of about 20 sccm, an O₂ gas flow rate of about 7 sccm, a microwave output of 500 W, and RF power of 500 W, employing Si as a metal target. Thereafter, the ZrO₂ film is formed on the SiO₂ film under conditions of an Ar gas flow rate of about 15 sccm, an O₂ gas flow rate of about 1.5 sccm, a microwave output of 500 W, and RF power of 500 W, employing Zr as a metal target. The three SiO₂ films and the three ZrO₂ films are alternately stacked, thereby forming the multilayer reflecting film 55. Thus, the facet coating film 9 is formed on the cavity facet 2b.

Finally, the wafer in a bar state is separated into chips along the ridge portion 2c, whereby the blue-violet semiconductor laser element 100 is formed.

According to the first embodiment, as hereinabove described, the facet coating film 8 includes the SiO₂ film 35 having a thickness (about 1095 nm) larger than the total thickness (about 128 nm) of the SiO₂ film 33 and the Al₂O₃ film 34 controlling the reflectance. The thickness of the SiO₂ film 35 is a thickness defined by m×λ/(2×n) and at least 1 μm. Thus, the thickness of the SiO₂ film 35 is larger than the total thickness of the SiO₂ film 33 and the Al₂O₃ film 34 and has no influence on the reflectance, and hence the SiO₂ film 33 and the Al₂O₃ film 34 can easily control the reflectance of the cavity facet 2a without any influence of the SiO₂ film 35. Further, the thick SiO₂ film 35 can effectively reduce the light density on the outermost surface 3a. Thus, formation of contaminants on the outermost surface 3a resulting from the reaction of water molecules in the atmosphere, low molecular siloxane or volatile organic gas present in minute amounts in the atmosphere, or the like with an emitted laser beam can be reliably inhibited. Consequently, the blue-violet semiconductor laser element 100 can stably operate.

According to the first embodiment, contaminants hardly adhere to the outermost surface 3a of an emitting facet, and hence no closed type package hermetically sealing the blue-violet semiconductor laser element 100 or the like is required.

According to the first embodiment, the SiO₂ film 35 includes a single layer film. Thus, an oxide film of SiO₂ having a small film stress is employed even if the thickness of the SiO₂ film 35 is large, at least 1 μm, and hence the film stress of the thick SiO₂ film 35 can be reduced as much as possible. Further, the SiO₂ film 35 has a single layer structure, and hence the SiO₂ film 35 can be easily formed in the manufacturing process.

According to the first embodiment, the SiO₂ film 33 and the Al₂O₃ film 34 are a dielectric film formed of two layers each having a thickness other than a thickness defined by m×λ/(2×n) (m is an integer). Thus, the “first dielectric layer” in the present invention for obtaining a desired reflectance can be formed by finely controlling the thickness of each of the SiO₂ film 33 and the Al₂O₃ film 34.

According to the first embodiment, each of the SiO₂ film 33 and the Al₂O₃ film 34 has a thickness of λ/(4×n) or approximately λ/(4×n). Thus, a desired reflectance can be easily obtained even if the “first dielectric layer” in the present invention is constituted by a dielectric film formed of two layers.

According to the first embodiment, the refractive index (about 1.48) of the SiO₂ film 35 is smaller than the refractive index (about 1.68) of the Al₂O₃ film 34. Thus, the thickness of the SiO₂ film 35 can be easily rendered larger than the total thickness of the SiO₂ film 33 and the Al₂O₃ film 34 serving as the “first dielectric layer” in the present invention.

According to the first embodiment, the Al₂O₃ film 34 and the SiO₂ film 35 are in contact with each other. Thus, another dielectric layer does not lie between the Al₂O₃ film 34 and the SiO₂ film 35, and hence the two layers of the SiO₂ film 33 and the Al₂O₃ film 34 can efficiently control the reflectance for an emitted laser beam while the SiO₂ film 35 can efficiently control the reduction in the light density of the emitted laser beam. Consequently, a laser beam, the reflectance for which and the light density of which are controlled to be desired ones, can be easily emitted from the outermost surface 3a of the facet coating film 8.

According to the first embodiment, the facet coating film 8 is formed by providing the SiO₂ film 33, the Al₂O₃ film 34 and the SiO₂ film 35 in this order from the side closer to the cavity facet 2a. Thus, the SiO₂ film 33 and the Al₂O₃ film 34 determining the reflectance can be brought close to the cavity facet 2a of the semiconductor element layer 2 hardly influenced by surface roughness, and hence the SiO₂ film 33 and the Al₂O₃ film 34, the thicknesses of which are more accurately controlled in a film forming process, can be formed. Thus, a desired reflectance can be accurately obtained.

According to the first embodiment, the SiO₂ film 35 is arranged on the outermost surface 3a of the facet coating film 8. Thus, the light density of an emitted laser beam is effectively reduced on the outermost surface 3a on which the SiO₂ film 35 is arranged, and hence formation of contaminants on the surface of the SiO₂ film 35 can be reliably inhibited. Thus, the blue-violet semiconductor laser element 100 in which the SiO₂ film 35 constituting the facet coating film 8 is inhibited from degradation can be obtained.

According to the first embodiment, a nitride-based semiconductor is employed as the semiconductor element layer 2. In the blue-violet semiconductor laser element 100 emitting a laser beam with a shorter wavelength (400 nm band) and requiring a higher output power, adherence of contaminants to the outermost surface 3a of an emitting facet tends to be significantly promoted due to an increase in the light density on the cavity facet 2a. Therefore, the blue-violet semiconductor laser element 100 includes the facet coating film 8 having the SiO₂ film 35, whereby adherence of contaminants to the outermost surface 3a of an emitting facet can be effectively reliably inhibited.

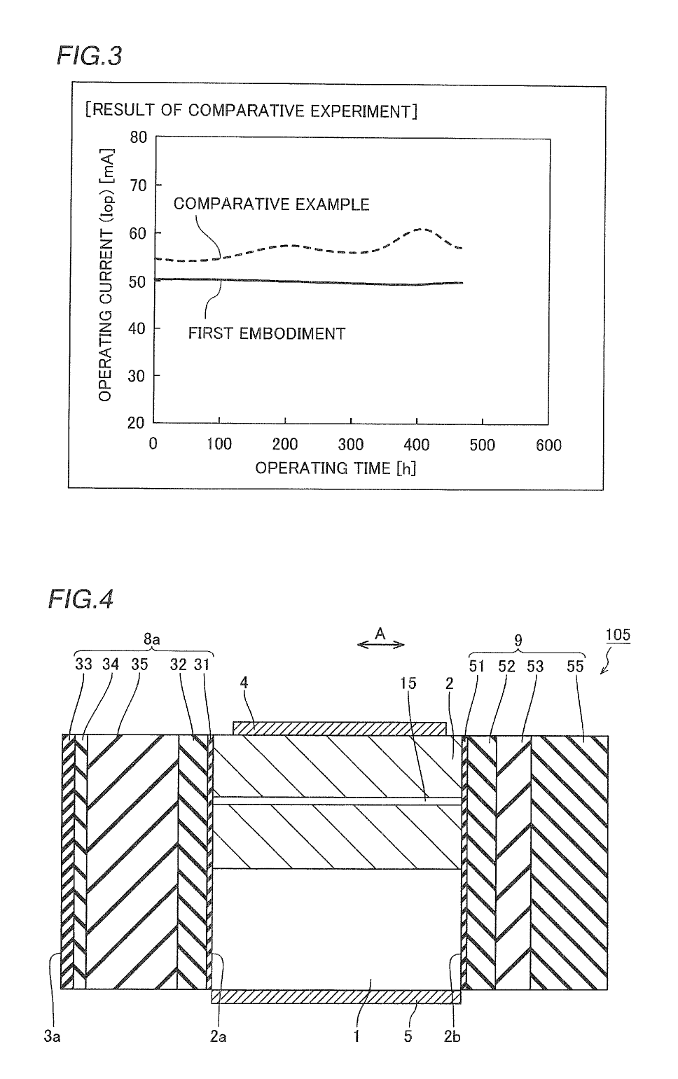

An experiment conducted to confirm usefulness of providing the SiO₂ film 35 in the aforementioned facet coating film 8 is now described with reference to FIG. 3.

As a comparative example, a blue-violet semiconductor laser element having a structure similar to that of the blue-violet semiconductor laser element 100 except that the SiO₂ film 35 is not formed on the outermost surface of an emitting facet was prepared. Then, the blue-violet semiconductor laser element 100 and the blue-violet semiconductor laser element according to the comparative example were mounted on respective open package type (open-to-atmosphere-type) semiconductor laser devices in which the blue-violet semiconductor laser element 100 and the blue-violet semiconductor laser element according to the comparative example are not hermetically sealed. Then, a life test was performed by adjusting the semiconductor laser elements to 20 mW output power by Automatic Power Control (APC) under a condition of 75° C. and continuously driving the same.

As a result, in the blue-violet semiconductor laser element 100, relatively stable current transition was shown with no fluctuation of an operating current even after 450 hours whereas in the blue-violet semiconductor laser element according to the comparative example, an operating current started to fluctuate immediately after operation and unstable current transition was shown, as shown in FIG. 3. In other words, in the blue-violet semiconductor laser element 100, the light density of a laser beam emitted from the cavity facet 2a and transmitted through the SiO₂ film 35 was conceivably effectively reduced on the outermost facet 3a of an emitting facet. Thus, it has been confirmed that adherence of contaminants to the outermost surface 3a and deposition of contaminants on the outermost surface 3a are inhibited. In consideration of the aforementioned results, usefulness of providing the SiO₂ film 35 in the facet coating film 8 has been confirmed.

### Modification of First Embodiment

A blue-violet semiconductor laser element 105 according to a modification of the first embodiment of the present invention is now described. This blue-violet semiconductor laser element 105 has a facet coating film 8a prepared by successively stacking an AlN film 31, an Al₂O₃ film 32, a SiO₂ film 35, an Al₂O₃ film 34, and a SiO₂ film 33 from the side closer to a cavity facet 2a, as shown in FIG. 4. In other words, the facet coating film 8a is formed by successively providing the “second dielectric layer” and the “first dielectric layer” in the present invention from the side closer to the cavity facet 2a. In the “first dielectric layer” in the present invention, the Al₂O₃ film 34 and the SiO₂ film 33 are successively stacked from the side closer to the cavity facet 2a. Therefore, the surface of the SiO₂ film 33 is an outermost surface 3a of an emitting facet. The blue-violet semiconductor laser element 105 is an example of the “semiconductor laser element” in the present invention. The remaining structure of the blue-violet semiconductor laser element 105 is similar to that of the aforementioned blue-violet semiconductor laser element 100 according to the first embodiment and denoted by the same reference numerals in the figure.

A manufacturing process for the blue-violet semiconductor laser element 105 is similar to the aforementioned manufacturing process for the blue-violet semiconductor laser element 100 according to the first embodiment except a step of stacking the AlN film 31, the Al₂O₃ film 32, the SiO₂ film 35, the Al₂O₃ film 34, and the SiO₂ film 33 in this order on the cavity facet 2a.

In the blue-violet semiconductor laser element 105, as hereinabove described, two layers of the Al₂O₃ film 34 and the SiO₂ film 33, and the SiO₂ film 35 in the facet coating film 8a are stacked in the opposite order to that in the blue-violet semiconductor laser element 100. Even in this case, a laser beam can be easily emitted from the outermost surface 3a in a state where the light density of the laser beam is reduced by the thicker SiO₂ film 35, and thereafter the reflectance is adjusted by the two layers of the thinner Al₂O₃ film 34 and SiO₂ film 33. Thus, the effects similar to those of the aforementioned first embodiment can be obtained.

### Second Embodiment

A blue-violet semiconductor laser element 200 according to a second embodiment of the present invention is now described. In this blue-violet semiconductor laser element 200, a SiO₂ film 36 having a thickness of about 1095 nm is provided also on the outermost surface of a facet coating film 9a, as shown in FIG. 5. In this case, the surface of the SiO₂ film 36 is an outermost surface 3b of a reflecting facet. The blue-violet semiconductor laser element 200 is an example of the “semiconductor laser element” in the present invention. The remaining structure of the blue-violet semiconductor laser element 200 is similar to that of the aforementioned blue-violet semiconductor laser element 100 according to the first embodiment and denoted by the same reference numerals in the figure.

In a manufacturing process for the blue-violet semiconductor laser element 200, the SiO₂ film 36 is formed on a multilayer reflecting film 55 through steps similar to those in the first embodiment. The remaining steps of the manufacturing process are similar to those of the aforementioned manufacturing process of the first embodiment.

In the blue-violet semiconductor laser element 200, as hereinabove described, the SiO₂ film 36 is provided also on the outermost surface of the facet coating film 9a, and hence contaminants can be inhibited from adhering to and being deposited on the outermost surface 3b of a reflecting facet. Thus, the intensity of a laser beam emitted from a cavity facet 2b can be stabilized. When the laser beam emitted from the cavity facet 2b is utilized as a monitor for controlling the intensity of a laser beam emitted from a cavity facet 2a, a monitor current obtained by detecting the intensity of the laser beam emitted from the cavity facet 2b can be stabilized. Consequently, the intensity of the laser beam emitted from the cavity facet 2a of the blue-violet semiconductor laser element 200 can be further stabilized. The remaining effects of the second embodiment are similar to those of the aforementioned first embodiment.

### Third Embodiment

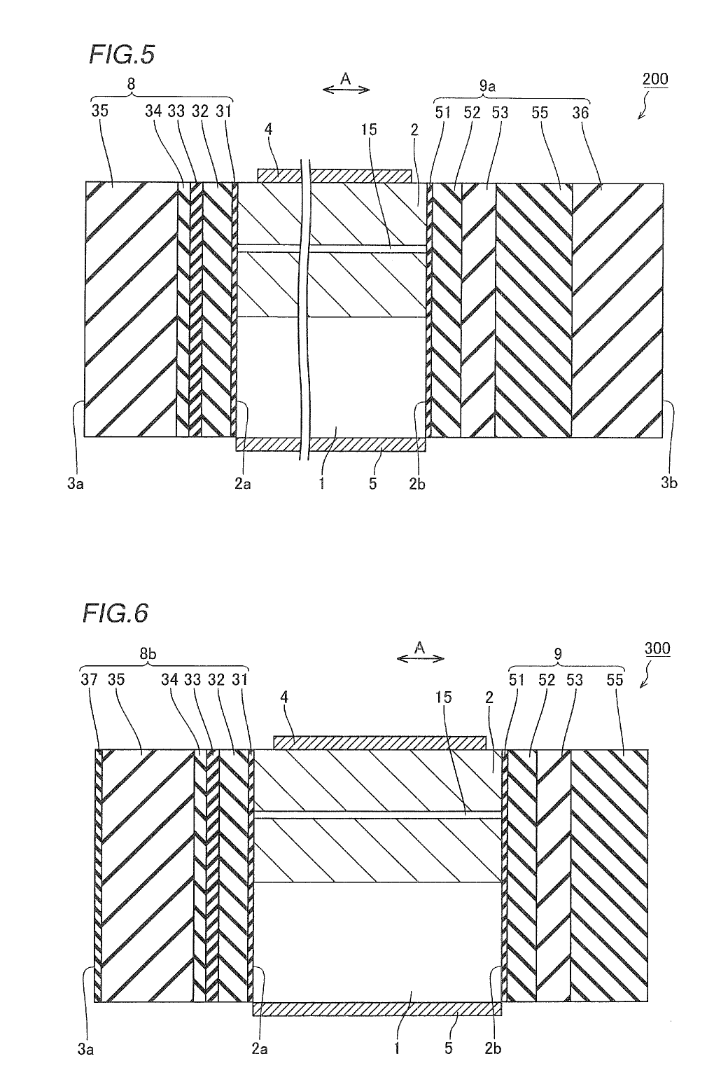

A blue-violet semiconductor laser element 300 according to a third embodiment of the present invention is now described. In this blue-violet semiconductor laser element 300, a TiO₂ film 37 having a thickness of about 78 nm is provided on the outermost surface of a facet coating film 8b, as shown in FIG. 6. In this case, the surface of the TiO₂ film 37 is an outermost surface 3a of an emitting facet. The blue-violet semiconductor laser element 300 is an example of the “semiconductor laser element” in the present invention. The TiO₂ film 37 is an example of the “third dielectric layer” in the present invention.

According to the third embodiment, a photocatalyst material of rutile type titanium dioxide is employed as the TiO₂ film 37. In the TiO₂ film 37, rutile type titanium dioxide and anatase-type titanium dioxide may be mixed. The TiO₂ film 37 includes a microcrystalline layer of TiO₂ and an amorphous layer of TiO₂. A portion of the TiO₂ film 37 corresponding to an active layer 15 may have a crystalline substance. The thickness (about 78 nm) of the TiO₂ film 37 is set by applying a relational expression shown by m×λ/(2×n) (m=1), where the refractive index of TiO₂ is n (=about 2.6).

The refractive index of the TiO₂ film 37 is larger than the refractive index of the SiO₂ film 35. When the “second dielectric layer” in the present invention has a multi-layer film structure of two or more layers, the refractive index of the TiO₂ film 37 is preferably larger than the refractive index of any one of dielectric layers constituting the “second dielectric layer”. Further, the refractive index of the TiO₂ film 37 is more preferably larger than the refractive index of each of the dielectric layers constituting the “second dielectric layer”. The remaining structure of the blue-violet semiconductor laser element 300 according to the third embodiment is similar to that of the aforementioned blue-violet semiconductor laser element 100 according to the first embodiment and denoted by the same reference numerals in the figure.

In a manufacturing process for the blue-violet semiconductor laser element 300, an AlN film 31 to a SiO₂ film 35 are formed on a cavity facet 2a through steps similar to those in the first embodiment. Thereafter, the TiO₂ film 37 is formed on the SiO₂ film 35 under conditions of an Ar gas flow rate of about 6 to about 8 sccm, an O₂ gas flow rate of about 2.4 to about 3 sccm, a microwave output of 600 W, RF power of 600 W, and a pressure in a film forming chamber of about 0.025 to about 0.035 Pa by ECR sputtering, employing Ti as a metal target. The remaining steps of the manufacturing process are similar to those of the aforementioned manufacturing process of the first embodiment.

In the blue-violet semiconductor laser element 300, as hereinabove described, the TiO₂ film 37 of a photocatalyst material is provided on the outermost surface 3a of the facet coating film 8b, and hence formation of contaminants on the outermost surface 3a of an emitting facet can be further inhibited due to photocatalytic action of the TiO₂ film 37.

In the blue-violet semiconductor laser element 300, the TiO₂ film 37 includes the microcrystalline layer of TiO₂ and the amorphous layer of TiO₂, and hence photocatalytic action of the “third dielectric layer” in the present invention can be reliably exerted.

In the blue-violet semiconductor laser element 300, the thickness of the TiO₂ film 37 is set to have the relation of m×λ/(2×n), and m is equal to 1 in the aforementioned expression. Thus, the absorption of a laser beam, the light density of which is properly reduced by the SiO₂ film 35, into the TiO₂ film 37 can be inhibited as much as possible. Thus, abnormal heat generation on the outermost surface 3a can be inhibited, and hence formation of contaminants on the outermost surface 3a can be more reliably inhibited. In contrast, laser characteristics tend to deteriorate due to an increase in the aforementioned absorption if the TiO₂ film 37 is thickened (m≧2). In this respect, it is not preferred to thicken the TiO₂ film 37 while it is preferred to form the TiO₂ film 37 more thinly than the SiO₂ film 35.

In the blue-violet semiconductor laser element 300, the refractive index (about 2.6) of the TiO₂ film 37 is larger than the refractive index (about 1.48) of the SiO₂ film 35, and hence the thickness of the TiO₂ film 37 can be easily rendered smaller (thinner) than the thickness of the SiO₂ film 35.

In the blue-violet semiconductor laser element 300, the facet coating film 8 has the “first dielectric layer”, the “second dielectric layer”, and the “third dielectric layer” in the present invention formed in this order from the side closer to the cavity facet 2a. Thus, in the facet coating film 8, an emitted laser beam is transmitted through the SiO₂ film 33 and the Al₂O₃ film 34 serving as the first dielectric layer to accurately obtain a desired reflectance, and thereafter transmitted through the SiO₂ film 35 serving as the second dielectric layer to properly reduce the light density, and thereafter transmitted through the TiO₂ film 37 serving as the third dielectric layer arranged on the outermost surface 3a, and hence formation of contaminants on the outermost surface 3a of an emitting facet can be effectively inhibited due to photocatalytic action of the TiO₂ film 37. The remaining effects of the third embodiment are similar to those of the aforementioned first embodiment.

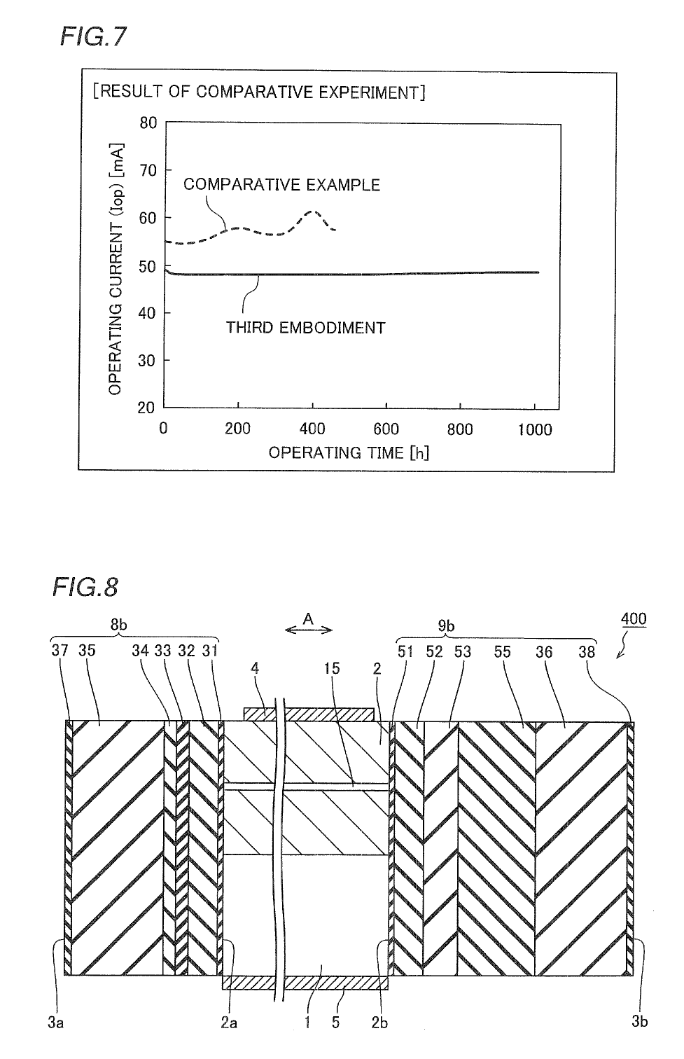

An experiment conducted to confirm usefulness of providing the TiO₂ film 37 in the aforementioned facet coating film 8b is now described with reference to FIGS. 3 and 7.

In a comparative example, the blue-violet semiconductor laser element prepared as the comparative example in the confirmatory experiment of the aforementioned first embodiment was employed. Then, the blue-violet semiconductor laser element 300 and the blue-violet semiconductor laser element according to the comparative example were mounted on respective open package type semiconductor laser devices in which the blue-violet semiconductor laser element 300 and the blue-violet semiconductor laser element according to the comparative example are not hermetically sealed. Then, a life test was performed by adjusting the semiconductor laser elements to 20 mW output power by APC under a condition of 75° C. and continuously driving the same.

As a result, in the blue-violet semiconductor laser element 300, stable current transition was shown with almost no fluctuation of an operating current even after 1000 hours as contrasted with the comparative example, as shown in FIG. 7. Moreover, the operating current transition (chronological change) of the blue-violet semiconductor laser element 300 was more constant than the operating current transition of the blue-violet semiconductor laser element 100 as compared with the experimental results (see FIG. 3) in the aforementioned first embodiment. In other words, it has been confirmed that adherence of contaminants to the outermost surface 3a and deposition of contaminants on the outermost surface 3a are further inhibited due to photocatalytic action of the TiO₂ film 37 in addition to the effect of the SiO₂ film 35 in the blue-violet semiconductor laser element 300. When the TiO₂ film 37 was formed, the deposition thickness of contaminants was about 5 nm after a 1000-hour life test, and it has been proved that this deposition thickness did not influence the characteristics of the element. From the aforementioned results, usefulness of providing the TiO₂ film 37 in the facet coating film 8b has been confirmed.

### Fourth Embodiment

A blue-violet semiconductor laser element 400 according to a fourth embodiment of the present invention is now described. In this blue-violet semiconductor laser element 400, a TiO₂ film 38 having a thickness of about 78 nm is provided on not only the outermost surface of a facet coating film 8b but also the outermost surface of a facet coating film 9b, as shown in FIG. 8. In this case, the surface of the TiO₂ film 38 is an outermost surface 3b of a reflecting facet. The blue-violet semiconductor laser element 400 is an example of the “semiconductor laser element” in the present invention. The remaining structure of the blue-violet semiconductor laser element 400 according to the fourth embodiment is similar to that of the aforementioned blue-violet semiconductor laser element 200 according to the second embodiment and denoted by the same reference numerals in the figure.

In a manufacturing process for the blue-violet semiconductor laser element 400, an AlN film 31 to a TiO₂ film 37 are formed on a cavity facet 2a through steps similar to those in the third embodiment, and an AlN film 51 to a SiO₂ film 36 are formed on a cavity facet 2b through steps similar to those in the second embodiment. Thereafter, the TiO₂ film 38 is formed on the SiO₂ film 36 through a step similar to that in the aforementioned third embodiment.

In the blue-violet semiconductor laser element 400, as hereinabove described, the TiO₂ film 38 is provided also on the outermost surface of the facet coating film 9b, and hence formation of contaminants on the outermost surface 3b of a reflecting facet can be further inhibited due to photocatalytic action of the TiO₂ film 38. Thus, a monitor current obtained by detecting the intensity of a laser beam emitted from the cavity facet 2b can be further stabilized, and hence the intensity of a laser beam emitted from the cavity facet 2a can be further stabilized. The remaining effects of the fourth embodiment are similar to those of the aforementioned second embodiment.

### Fifth Embodiment

A blue-violet semiconductor laser element 500 according to a fifth embodiment of the present invention is now described. In this blue-violet semiconductor laser element 500, an AlN film 39 having a thickness of about 10 nm is provided between a SiO₂ film 35 and a TiO₂ film 37 in a facet coating film 8c, as shown in FIG. 9. The blue-violet semiconductor laser element 500 is an example of the “semiconductor laser element” in the present invention. The remaining structure of the blue-violet semiconductor laser element 500 according to the fifth embodiment is similar to that of the aforementioned blue-violet semiconductor laser element 300 according to the third embodiment and denoted by the same reference numerals in the figure.

A manufacturing process for the blue-violet semiconductor laser element 500 is similar to the aforementioned manufacturing process for the blue-violet semiconductor laser element 300 according to the third embodiment except a step of forming the AlN film 39 serving as an underlayer of the TiO₂ film 37 on the SiO₂ film 35 before forming the TiO₂ film 37 on an outermost surface 3a of the facet coating film 8c. A film forming process for the AlN film 39 is similar to a film forming process for an AlN film 31. The thickness of the AlN film 39 is preferably not more than 10 nm described above.

In the blue-violet semiconductor laser element 500, as hereinabove described, the AlN film 39 serving as the underlayer is provided between the SiO₂ film 35 and the TiO₂ film 37, whereby the TiO₂ film 37 can be improved in crystallinity by the AlN film 39. Thus, the photocatalytic effect of the TiO₂ film 37 can be enhanced. The remaining effects of the fifth embodiment are similar to those of the aforementioned third embodiment.

### Sixth Embodiment

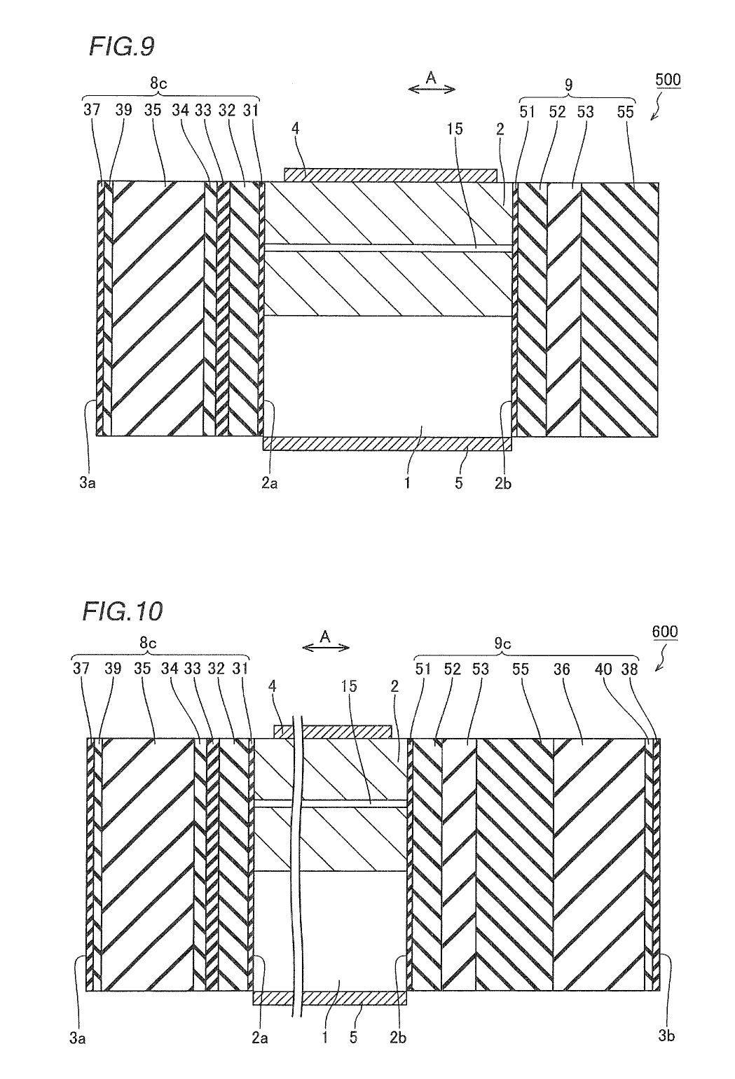

A blue-violet semiconductor laser element 600 according to a sixth embodiment of the present invention is now described. In this blue-violet semiconductor laser element 600, an AlN film 40 having a thickness of about 10 nm is provided between a SiO₂ film 36 and a TiO₂ film 38 in not only a facet coating film 8c but also a facet coating film 9c, as shown in FIG. 10. The blue-violet semiconductor laser element 600 is an example of the “semiconductor laser element” in the present invention. The remaining structure of the blue-violet semiconductor laser element 600 according to the sixth embodiment is similar to that of the aforementioned blue-violet semiconductor laser element 400 according to the fourth embodiment and denoted by the same reference numerals in the figure.

A manufacturing process for the blue-violet semiconductor laser element 600 is substantially similar to the aforementioned manufacturing process for the blue-violet semiconductor laser element 500 according to the fifth embodiment except a step of forming the AlN film 40 serving as an underlayer of the TiO₂ film 38 on the SiO₂ film 36 before forming the TiO₂ film 38 on an outermost surface 3b of the facet coating film 9c.

In the blue-violet semiconductor laser element 600, as hereinabove described, the AlN film 40 is provided between the SiO₂ film 36 and the TiO₂ film 38, whereby the TiO₂ film 38 can be improved in crystallinity by the AlN film 40. Thus, the photocatalytic effects of not only the TiO₂ film 37 but also the TiO₂ film 38 can be enhanced. The remaining effects of the sixth embodiment are similar to those of the aforementioned fourth embodiment.

### Seventh Embodiment

A blue-violet semiconductor laser element 700 according to a seventh embodiment of the present invention is now described. In this blue-violet semiconductor laser element 700, a dielectric layer 41 formed between an Al₂O₃ film 34 and a TiO₂ film 37 is constituted by a plurality of dielectric layers, as shown in FIG. 11. The blue-violet semiconductor laser element 700 is an example of the “semiconductor laser element” in the present invention, and the dielectric layer 41 is an example of the “second dielectric layer” in the present invention.

Specifically, the dielectric layer 41 has a structure obtained by alternately stacking two SiO₂ films 42 each having a thickness of about 410 nm and two AlON films 43 each having a thickness of about 107 nm successively from the side closer to the Al₂O₃ film 34, and has a total thickness (at least 1 μm) of about 1039 nm. The thickness (about 410 nm) of the SiO₂ film 42 is set by applying a relational expression shown by m×λ/(2×n) (m=3). The thickness (about 107 nm) of the AlON film 43 is set by applying a relational expression shown by m×λ/(2×n) (m=1), where the refractive index of AlON is n (=about 1.89). The SiO₂ films 42 and the AlON films 43 are examples of the “first layer” and the “second layer” in the present invention, respectively.

The refractive index (=about 1.48) of the SiO₂ film 42 is smaller than the refractive index (=about 1.68) of the Al₂O₃ film 34 whereas the refractive index (=about 1.89) of the AlON film 43 is larger than the refractive index of each of the SiO₂ film 33 and the Al₂O₃ film 34. When the “second dielectric layer” in the present invention has a multi-layer film structure of two or more layers as in the seventh embodiment, the refractive index of any one of dielectric layers constituting the “second dielectric layer” may simply be smaller than the refractive index of any one of dielectric layers constituting the “first dielectric layer” in the present invention.

The refractive index of the TiO₂ film 37 is larger than the refractive index of each of the SiO₂ films 42 and the AlON films 43 constituting the dielectric layer 41. The remaining structure of the blue-violet semiconductor laser element 700 according to the seventh embodiment is similar to that of the aforementioned blue-violet semiconductor laser element 300 according to the third embodiment and denoted by the same reference numerals in the figure.

A manufacturing process for the blue-violet semiconductor laser element 700 is similar to the aforementioned manufacturing process of the third embodiment except that the dielectric layer 41 is formed in place of the SiO₂ film 35.

In the blue-violet semiconductor laser element 700, as hereinabove described, the dielectric layer 41 has a multi-layer film structure obtained by alternately stacking the two SiO₂ films 42 and the two AlON films 43, and each layer is set to a thickness defined by m×λ/(2×n). Thus, the dielectric layer 41 is constituted by the SiO₂ films 42 and the AlON films 43 each having a thickness not influencing the reflectance, and hence a SiO₂ film 33 and the Al₂O₃ film 34 can easily control the reflectance of a cavity facet 2a without any influence of the dielectric layer 41 even if the dielectric layer 41 has a multi-layer film structure. Further, the dielectric layer 41 can be formed by alternately arranging an oxynitride film (AlON film 43) with a relatively larger film stress and an oxide film (SiO₂ film 42) with a relatively smaller film stress, and hence the thick dielectric layer 41 can be easily formed while an excessive increase in the film stress is inhibited.

In the blue-violet semiconductor laser element 700, the thickness of the SiO₂ film 42 is larger than the thickness of the AlON film 43 in the dielectric layer 41. Thus, the thickness of the AlON film 43 of an oxynitride film with a relatively larger film stress is rendered smaller than the thickness of the SiO₂ film 42 of an oxide film with a relatively smaller film stress to form the dielectric layer 41, and hence an excessive increase in the film stress of the thick dielectric layer 41 can be inhibited.

In the blue-violet semiconductor laser element 700, the refractive index of the TiO₂ film 37 is larger than the refractive index of each of the SiO₂ films 42 and the AlON films 43 constituting the dielectric layer 41. Thus, the thickness of the TiO₂ film 37 can be reliably rendered smaller (thinner) than the total thickness of the dielectric layer 41 having a multi-layer film structure.

The remaining effects of the seventh embodiment are similar to those of the aforementioned third embodiment.

### Eighth Embodiment

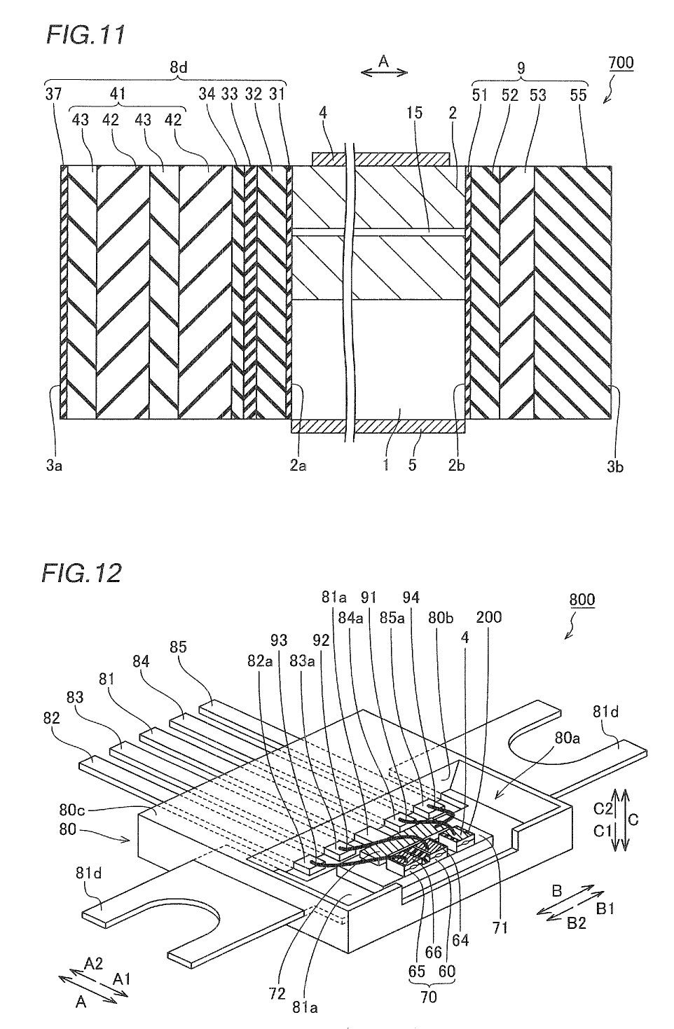

The structure of a three-wavelength semiconductor laser device 800 according to an eighth embodiment of the present invention is now described with reference to FIG. 12. The three-wavelength semiconductor laser device 800 is an example of the “semiconductor laser device” in the present invention.

In the three-wavelength semiconductor laser device 800 according to the eighth embodiment of the present invention, the aforementioned blue-violet semiconductor laser element 200 according to the second embodiment and a two-wavelength semiconductor laser element 70 having a red semiconductor laser element 60 with a lasing wavelength of about 650 nm and an infrared semiconductor laser element 65 with a lasing wavelength of about 780 nm monolithically formed are bonded onto the bottom surface of a protruding block 80a of a substantially tabular base body 80 made of an insulator (resin) through a submount 71. The three-wavelength semiconductor laser device 800 is an open package type semiconductor laser device in which the blue-violet semiconductor laser element 200 and the two-wavelength semiconductor laser element 70 are exposed on the protruding block 80a. The base body 80 is an example of the “open-to-atmosphere-type package” in the present invention.

The blue-violet semiconductor laser element 200 and the two-wavelength semiconductor laser element 70 are mounted in a junction-up system such that respective laser beam-emitting facets face outward (in a direction Al) and are adjacent to each other at a prescribed interval in the width direction (direction B).

The base body 80 is provided with lead terminals 81, 82, 83, 84, and 85 each made of a metal lead frame. These lead terminals 81 to 85 are arranged to pass through the base body 80 from the front side (A1 side) to the rear side (A2 side) in a state insulated from each other by resin mold. Rear end regions extending to the outside (A2 side) of the base body 80 each are connected to a driving circuit (not shown). Front end regions 81a, 82a, 83a, 84a, and 85a of the lead terminals 81 to 85 extending to the front side (A1 side) are exposed from an inner wall surface 80b of the base body 80 constituting the protruding block 80a and arranged on the bottom surface of the protruding block 80a. The bottom surface of the protruding block 80a is formed to have a prescribed depth downward (in a direction C1) from the upper surface 80c (C2 side) of the base body 80. The front end region 81a widens in the direction B on the bottom surface of the protruding block 80a on the front side (Al side) of the front end regions 82a to 85a.

The lead terminal 81 is integrally formed with a pair of heat radiation portions 81d connected to the front end region 81a. The heat radiation portions 81d are arranged substantially symmetrically about the lead terminal 81 on both sides in the direction B. The heat radiation portions 81d extend from the front end region 81a and pass through the base body 80 in directions B1 and B2 from the side surfaces to be exposed.

A first end of a metal wire 91 is bonded to a p-side electrode 4, and a second end of the metal wire 91 is connected to the front end region 84a of the lead terminal 84. A first end of a metal wire 92 is bonded to a surface electrode 64 formed on the upper surface of the red semiconductor laser element 60, and a second end of the metal wire 92 is connected to the front end region 83a of the lead terminal 83. A first end of a metal wire 93 is bonded to a surface electrode 66 formed on the upper surface of the infrared semiconductor laser element 65, and a second end of the metal wire 93 is connected to the front end region 82a of the lead terminal 82. An n-side electrode (not shown) formed on the lower surface of the blue-violet semiconductor laser element 200 and an n-side electrode (not shown) formed on the lower surface of the two-wavelength semiconductor laser element 70 are electrically connected to the front end region 81a of the lead terminal 81 through the submount 71.

A photodiode (PD) 72 employed to monitor the intensity of laser beams is arranged on a rear portion (on the A2 side) of the submount 71 closer to the cavity facet 2b of the blue-violet semiconductor laser element 200 such that a photosensitive surface thereof faces upward (in a direction C2). The lower surface of the PD 72 is electrically connected to the submount 71. A first end of a metal wire 94 made of Au or the like is bonded onto the upper surface of the PD 72, and a second end of the metal wire 94 is connected to the front end region 85a of the lead terminal 85.

The three-wavelength semiconductor laser device 800 includes the aforementioned blue-violet semiconductor laser element 200. Thus, the reliable three-wavelength semiconductor laser device 800 capable of stably operating the blue-violet semiconductor laser element 200 and enduring the use for a long time can be obtained. Further, the three-wavelength semiconductor laser device 800 includes the open-to-atmosphere-type package not requiring hermetic sealing, and hence the structure of the three-wavelength semiconductor laser device 800 can be simplified.

### Ninth Embodiment

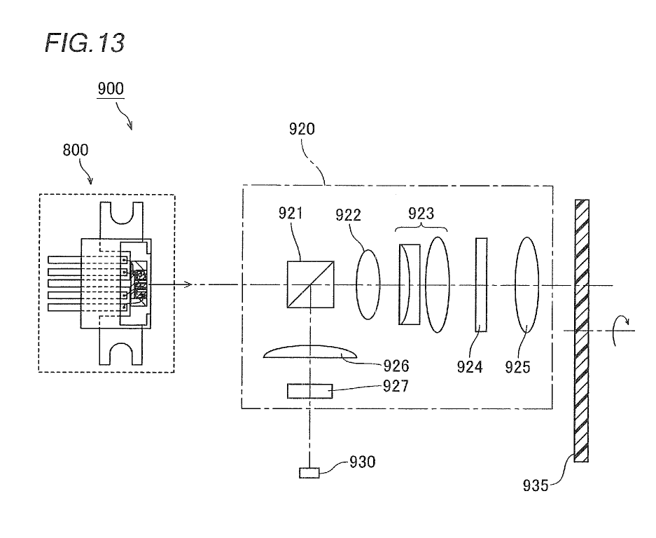

The structure of an optical pickup 900 according to a ninth embodiment of the present invention is now described with reference to FIG. 13. The optical pickup 900 is an example of the “optical apparatus” in the present invention.

The optical pickup 900 according to the ninth embodiment of the present invention stores the aforementioned three-wavelength semiconductor laser device 800 according to the eighth embodiment. The optical pickup 900 includes the three-wavelength semiconductor laser device 800, an optical system 920 adjusting laser beams emitted from the three-wavelength semiconductor laser device 800, and a light detection portion 930 receiving the laser beams.

The optical system 920 has a polarizing beam splitter (PBS) 921, a collimator lens 922, a beam expander 923, a λ/4 plate 924, an objective lens 925, a cylindrical lens 926, and an optical axis correction device 927.

The PBS 921 totally transmits the laser beams emitted from the three-wavelength semiconductor laser device 800, and totally reflects the laser beams fed back from an optical disc 935. The collimator lens 922 converts the laser beams emitted from the three-wavelength semiconductor laser device 800 and transmitted through the PBS 921 to parallel beams. The beam expander 923 is constituted by a concave lens, a convex lens, and an actuator (not shown). The actuator has a function of correcting wave surface states of the laser beams emitted from the three-wavelength semiconductor laser device 800 by varying a distance between the concave lens and the convex lens in response to a servo signal from a servo circuit described later.

The λ/4 plate 924 converts the linearly polarized laser beams, substantially converted to the parallel beams by the collimator lens 922, to circularly polarized beams. Further, the λ/4 plate 924 converts the circularly polarized laser beams fed back from the optical disc 935 to linearly polarized beams. A direction of linear polarization in this case is orthogonal to a direction of linear polarization of the laser beams emitted from the three-wavelength semiconductor laser device 800. Thus, the PBS 921 substantially totally reflects the laser beams fed back from the optical disc 935. The objective lens 925 converges the laser beams transmitted through the λ/4 plate 924 on a surface (recording layer) of the optical disc 935. An objective lens actuator (not shown) renders the objective lens 925 movable in a focus direction, a tracking direction and a tilt direction in response to servo signals (a tracking servo signal, a focus servo signal, and a tilt servo signal) from the servo circuit described later.

The cylindrical lens 926, the optical axis correction device 927, and the light detection portion 930 are arranged to be along optical axes of the laser beams totally reflected by the PBS 921. The cylindrical lens 926 provides the incident laser beams with astigmatic action. The optical axis correction device 927 is constituted by a diffraction grating and so arranged that spots of zero-order diffracted beams of blue-violet, red, and infrared laser beams transmitted through the cylindrical lens 926 coincide with each other on a detection region of the light detection portion 930 described later.

The light detection portion 930 outputs a playback signal on the basis of intensity distribution of the received laser beams. The light detection portion 930 has a detection region of a prescribed pattern, to obtain a focus error signal, a tracking error signal, and a tilt error signal along with the playback signal. Thus, the optical pickup 900 including the three-wavelength semiconductor laser device 800 is formed.

In this optical pickup 900, the three-wavelength semiconductor laser device 800 can independently emit blue-violet, red, and infrared laser beams from the blue-violet semiconductor laser element 200, the red semiconductor laser element 60, and the infrared semiconductor laser element 65 by independently applying voltages between the lead terminal 81 and the lead terminals 82 to 84, respectively. The laser beams emitted from the three-wavelength semiconductor laser device 800 are adjusted by the PBS 921, the collimator lens 922, the beam expander 923, the λ/4 plate 924, the objective lens 925, the cylindrical lens 926, and the optical axis correction device 927 as described above, and thereafter applied onto the detection region of the light detection portion 930.

When data recorded in the optical disc 935 is play backed, the laser beams emitted from the blue-violet semiconductor laser element 200, the red semiconductor laser element 60, and the infrared semiconductor laser element 65 are controlled to have constant power and applied to the recording layer of the optical disc 935, so that the playback signal output from the light detection portion 930 can be obtained. The actuator of the beam expander 923 and the objective lens actuator driving the objective lens 925 can be feedback-controlled by the focus error signal, the tracking error signal, and the tilt error signal simultaneously output.

When data is recorded in the optical disc 935, the laser beams emitted from the blue-violet semiconductor laser element 200 and the red semiconductor laser element 60 (infrared semiconductor laser element 65) are controlled in power and applied to the optical disc 935, on the basis of the data to be recorded. Thus, the data can be recorded in the recording layer of the optical disc 935. Similarly to the above, the actuator of the beam expander 923 and the objective lens actuator driving the objective lens 925 can be feedback-controlled by the focus error signal, the tracking error signal, and the tilt error signal output from the light detection portion 930.

Thus, the data can be recorded in or played back from the optical disc 935 with the optical pickup 900 including the three-wavelength semiconductor laser device 800.

The optical pickup 900 is mounted with the aforementioned three-wavelength semiconductor laser device 800. Thus, the optical pickup 900 mounted with the reliable three-wavelength semiconductor laser device 800 capable of enduring the use for a long time can be easily obtained.

Although the present invention has been described and illustrated in detail, it is clearly understood that the same is by way of illustration and example only and is not to be taken by way of limitation, the spirit and scope of the present invention being limited only by the terms of the appended claims.

For example, while the “first dielectric layer” in the present invention is formed by stacking the SiO₂ film 33 and the Al₂O₃ film 34, which both are oxide films, in each of the aforementioned first to ninth embodiments, the present invention is not restricted to this, but the “first dielectric layer” in the present invention may be formed employing a nitride film, an oxide film and an oxynitride film. In this case, a nitride film containing an Al element or a Si element can be employed as the nitride film. An oxide film and an oxynitride film containing an Al element, a Si element, a Zr element, a Ta element, a Hf element, a Nb element, a Ti element, or the like can be employed as the oxide film and the oxynitride film. Thus, the reflectance of the first dielectric layer can be properly controlled to be at least about 20% by forming a multilayer film of a low refractive index layer and a high refractive index layer. Further, the facet coating film 9 on the side of the cavity facet 2b may be formed of an inorganic dielectric layer of the material shown in the aforementioned modification in addition to the material shown in each of the aforementioned first to ninth embodiments. Thus, the reflectance of the facet coating film 9 can be properly controlled to be at least about 50%.

While the “first dielectric layer” in the present invention has a multi-layer film structure obtained by stacking the SiO₂ film 33 and the Al₂O₃ film 34 in each of the aforementioned first to ninth embodiments, in the present invention, the “first dielectric layer” in the present invention may be formed of a single layer film.

While the SiO₂ film 35 (refractive index: about 1.48) serving as the “second dielectric layer” in the present invention is about 1095 nm in each of the aforementioned first to sixth, eighth and ninth embodiments, in the present invention, m is preferably not more than 18 in the relational expression shown by m×λ/(2×n) as to the thickness (total thickness) of the “second dielectric layer”. In this case, the thickness (total thickness) of the “second dielectric layer” is preferably about 2.0 μm.

While the “second dielectric layer” in the present invention is formed of a single layer film of the SiO₂ film 35 in each of the aforementioned first to sixth, eighth and ninth embodiments, the present invention is not restricted to this, but the “second dielectric layer” in the present invention may be formed of a single layer film of an oxide film containing an Al element, a Zr element, a Ta element, a Hf element, a Nb element, a Ti element, or the like.

If the “second dielectric layer” in the present invention is formed of an Al₂O₃ film (refractive index: about 1.68), for example, m is preferably not more than 21 in the relational expression shown by m×λ/(2×n) as to the thickness of the Al₂O₃ film. Alternatively, if the “second dielectric layer” in the present invention is formed of a Ta₂O₅ film (refractive index: about 2.1), m is preferably not more than 26 in the relational expression shown by m×λ/(2×n) as to the thickness of the Ta₂O₅ film. Alternatively, if the “second dielectric layer” in the present invention is formed of a ZrO₂ film (refractive index: about 2.2), m is preferably not more than 28 in the relational expression shown by m×λ/(2×n) as to the thickness of the ZrO₂ film. Alternatively, if the “second dielectric layer” in the present invention is formed of a TiO₂ film (refractive index: about 2.6), m is preferably not more than 33 in the relational expression shown by m×λ/(2×n) as to the thickness of the TiO₂ film. The “second dielectric layer” and the “first dielectric layer” in the present invention are preferably formed such that the refractive index n2 of the “second dielectric layer” is smaller than the refractive index n1 of the “first dielectric layer”.

While the dielectric layer 41 having a multi-layer film structure is provided in the facet coating film 8d in the aforementioned seventh embodiment, the present invention is not restricted to this. In the present invention, the dielectric layer 41 may be formed also in the facet coating film 9 on the side of the reflecting facet. Alternatively, this dielectric layer 41 having a multi-layer film structure may be formed in place of the SiO₂ film 36 in each of the aforementioned second, fourth, and sixth embodiments.

While the dielectric layer 41 is formed by alternately stacking the two SiO₂ films 42 and the two AlON films 43 successively from the side closer to the Al₂O₃ film 34 in the aforementioned seventh embodiment, the present invention is not restricted to this. In the present invention, the three or more SiO₂ films 42 and the three or more AlON films 43 may be alternately stacked. Alternatively, the SiO₂ films 42 and the AlON films 43 may be alternately stacked in the opposite order to that described above. As to the thickness of the oxynitride film (the AlON film 43 or the like) constituting the dielectric layer 41, m is preferably equal to 1 in the relational expression shown by m×λ/(2×n).

While the “third dielectric layer” in the present invention is formed of a single layer film of the TiO₂ film 37 in each of the aforementioned third to seventh embodiments, the present invention is not restricted to this, but the “third dielectric layer” in the present invention may be formed of a single layer film of an oxynitride film. Alternatively, the oxide film may be an oxide film containing a W element in addition to the TiO₂ film 37. Alternatively, an oxynitride film containing a Ti element or a W element can be employed as the oxynitride film.

While the “third dielectric layer” in the present invention is formed of a photocatalyst material of TiO₂ in each of the aforementioned third to seventh embodiments, the present invention is not restricted to this. In the present invention, the “third dielectric layer” in the present invention may be formed of a photocatalyst material of TiO₂ doped with N, TiO₂ doped with C, TiO₂ doped with S, or the like other than TiO₂.

While the multilayer reflecting film 55 controlling the reflectance of the cavity facet 2b is formed by alternately stacking the three SiO₂ films and the three ZrO₂ films in each of the aforementioned first to ninth embodiments, the present invention is not restricted to this. In the present invention, the SiO₂ films and the ZrO₂ films may be alternately stacked in numbers other than three. Further, different two types of insulating films having other refractive indices other than the SiO₂ films and the ZrO₂ films may be combined as the multilayer reflecting film.

While the optical pickup 900 including the “semiconductor laser device” in the present invention has been shown in the aforementioned ninth embodiment, the present invention is not restricted to this, but the semiconductor laser device in the present invention may be applied to an optical disc apparatus performing record in an optical disc such as a CD, a DVD, or a BD and playback of the optical disc and an optical apparatus such as a projector.

While the “facet coating film” in the present invention is formed with the ECR sputtering film deposition apparatus in each of the manufacturing processes of the aforementioned first to seventh embodiments, the present invention is not restricted to this, but the facet coating film may be formed by another film deposition method.

What is claimed is:

1. A semiconductor laser element comprising:
a semiconductor element layer including an active layer and having an emitting side cavity facet and a reflecting side cavity facet; and
a facet coating film on a surface of said emitting side cavity facet, wherein
said facet coating film includes a first dielectric layer controlling a reflectance of said emitting side cavity facet and a second dielectric layer, and
a thickness of said second dielectric layer is set to a thickness defined by m×λ/(2×n) (m is an integer), where a wavelength of a laser beam emitted from said active layer is λ and a refractive index of said second dielectric layer is n, and is larger than a thickness of said first dielectric layer and at least 1 μm.

2. The semiconductor laser element according to claim 1, wherein
said second dielectric layer is made of a SiO₂ film.

3. The semiconductor laser element according to claim 1, wherein
said second dielectric layer has a multi-layer film structure made of a plurality of dielectric layers, and a thickness of each of said plurality of dielectric layers is set to a thickness defined by m×λ/(2×n) (m is an integer), where said wavelength of said laser beam emitted from said active layer is λ and a refractive index of each of said plurality of dielectric layers is n, and said thickness of said second dielectric layer is larger than said thickness of said first dielectric layer and at least 1 μm.

4. The semiconductor laser element according to claim 3, wherein
said second dielectric layer has said multi-layer film structure obtained by stacking a first layer of SiO₂ and a second layer of AlON, and
a thickness of said first layer is larger than a thickness of said second layer.

5. The semiconductor laser element according to claim 4, wherein
at least two said first layers and at least two said second layers are alternately stacked in said second dielectric layer.

6. The semiconductor laser element according to claim 1, wherein
said first dielectric layer is a single-layer dielectric film having a thickness other than a thickness defined by m×λ/(2×n) (m is an integer) or a dielectric film made of a plurality of layers each having a thickness other than a thickness defined by m×λ/(2×n) (m is an integer).

7. The semiconductor laser element according to claim 6, wherein
at least one layer of said dielectric film has a thickness of λ/(4×n) or approximately λ/(4×n) if said first dielectric layer is said dielectric film made of said plurality of layers.

8. The semiconductor laser element according to claim 1, wherein
said refractive index of said second dielectric layer is smaller than a refractive index of said first dielectric layer.

9. The semiconductor laser element according to claim 1, wherein
said first dielectric layer and said second dielectric layer are in contact with each other.

10. The semiconductor laser element according to claim 1, wherein
said first dielectric layer and said second dielectric layer are formed in this order from a side closer to said emitting side cavity facet in said facet coating film.

11. The semiconductor laser element according to claim 10, wherein
said second dielectric layer is arranged on an outermost surface of said facet coating film.

12. The semiconductor laser element according to claim 1, wherein
said facet coating film further includes a third dielectric layer made of a photocatalyst material on an outermost surface opposite to said emitting side cavity facet.

13. The semiconductor laser element according to claim 12, wherein
said third dielectric layer includes a microcrystalline layer of TiO₂ and an amorphous layer of TiO₂.

14. The semiconductor laser element according to claim 12, wherein
a thickness of said third dielectric layer is set to a thickness defined by m×λ/(2×n) (m is an integer) and is smaller than said thickness of said second dielectric layer.

15. The semiconductor laser element according to claim 12, wherein
a refractive index of said third dielectric layer is larger than said refractive index of said second dielectric layer.

16. The semiconductor laser element according to claim 12, wherein
said first dielectric layer, said second dielectric layer, and said third dielectric layer are formed in this order from a side closer to said emitting side cavity facet in said facet coating film.

17. The semiconductor laser element according to claim 16, wherein
said third dielectric layer is formed on said second dielectric layer through a nitride film.

18. The semiconductor laser element according to claim 1, wherein
said semiconductor element layer is made of a nitride-based semiconductor.

19. A semiconductor laser device comprising:
a semiconductor laser element including a semiconductor element layer including an active layer and having an emitting side cavity facet and a reflecting side cavity facet, and a facet coating film on a surface of said emitting side cavity facet; and
an open-to-atmosphere-type package mounting with said semiconductor laser element, wherein
said facet coating film has a first dielectric layer controlling a reflectance of said emitting side cavity facet and a second dielectric layer, and
a thickness of said second dielectric layer is set to a thickness defined by m×λ/(2×n) (m is an integer), where a wavelength of a laser beam emitted from said active layer is λ and a refractive index of said second dielectric layer is n, and is larger than a thickness of said first dielectric layer and at least 1 μm.

20. An optical apparatus comprising:
a semiconductor laser device including a semiconductor laser element having a semiconductor element layer including an active layer and having an emitting side cavity facet and a reflecting side cavity facet, and a facet coating film on a surface of said emitting side cavity facet, and an open-to-atmosphere-type package mounting with said semiconductor laser element; and
an optical system controlling a beam emitted from said semiconductor laser element, wherein
said facet coating film has a first dielectric layer controlling a reflectance of said emitting side cavity facet and a second dielectric layer, and
a thickness of said second dielectric layer is set to a thickness defined by m×λ/(2×n) (m is an integer), where a wavelength of a laser beam emitted from said active layer is λ and a refractive index of said second dielectric layer is n, and is larger than a thickness of said first dielectric layer and at least 1 μm.
